(19) United States
(12) Patent Application Publication
(10) Pub. No.: US 2026/0006765 A1
(43) Pub. Date: Jan. 1, 2026

(54) STATIC RANDOM-ACCESS MEMORY DEVICE

(71) Applicant: United Microelectronics Corp., Hsinchu (TW)

(72) Inventors: Chun-Hsien HUANG, Tainan City (TW); Yu-Tse KUO, Tainan City (TW); Shu-Ru WANG, Taichung City (TW); Chien-Hung CHEN, Taipei City (TW); Tzu-Feng CHANG, Tainan City (TW); Chun-Yen TSENG, Tainan City (TW)

(21) Appl. No.: 18/796,378

(22) Filed: Aug. 7, 2024

(30) Foreign Application Priority Data
Jun. 26, 2024 (TW) 113123731

(51) Int. Cl. H10B 10/00

(52) U.S. Cl. CPC H10B 10/12

(57) ABSTRACT

Static random-access memory devices are provided. The static random-access memory device includes a first static random-access memory cell, a second static random-access memory cell adjacent to the first static random-access memory cell, an isolation structure between the first and second static random-access memory cells, a first dummy gate structure and a second dummy gate structure. The first dummy gate structure and the second dummy gate structure are on the isolation structure, between the first and second static random-access memory cells, and disposed along a first direction. A width of the isolation structure along the first direction is greater than or equal to a distance between a first sidewall of the first dummy gate structure facing away from the second dummy gate structure and a second sidewall of the second dummy gate structure facing away from the first dummy gate structure along the first direction.

This application claims the benefit of Taiwan application Serial No. 113123731, filed Jun. 26, 2024, the subject matter of which is incorporated herein by reference.

### BACKGROUND

### Technical Field

The disclosure relates to a memory device, and more particularly relates to static random-access memory devices.

### Description of the Related Art

Static random-access memory (SRAM) devices refers to storage devices that hold data permanently in the presence of power. As integrated circuit (IC) technologies progress towards smaller technology nodes, static random-access memory devices often incorporate fin-based structures, such as fin field-effect transistor structures (FinFET), into static random-access memory cells to enhance performance. However, the problem of leakage current is likely to occur in the existing design of fin field-effect transistor structures, which may affect the electrical performance of the memory device.

### SUMMARY

According to an embodiment of the present disclosure, a static random-access memory device is provided. The static random-access memory device includes a first static random-access memory cell, a second static random-access memory cell adjacent to the first static random-access memory cell, an isolation structure between the first static random-access memory cell and the second static random-access memory cell, a first dummy gate structure on the isolation structure and between the first static random-access memory cell and the second static random-access memory cell, and a second dummy gate structure on the isolation structure and between the first static random-access memory cell and the second static random-access memory cell. The first dummy gate structure and the second dummy gate structure are disposed along a first direction. a width of the isolation structure along the first direction is greater than or equal to a distance between a first sidewall of the first dummy gate structure and a second sidewall of the second dummy gate structure along the first direction. The first sidewall faces away from the second dummy gate structure. The second sidewall faces away from the first dummy gate structure.

According to another embodiment of the present disclosure, a static random-access memory device is provided. The static random-access memory device includes a plurality of static random-access memory cells, an isolation structure between adjacent two static random-access memory cells of the plurality of static random-access memory cells, and a first dummy gate element on the isolation structure. Each of the plurality of static random-access memory cells includes two pull-up transistors, two pull-down transistors and two pass-gate transistors. A lower surface of the first dummy gate element is entirely covered by the isolation structure.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic top view of a static random-access memory device according to some embodiments of the present disclosure.

FIG. 2 illustrates a schematic partial top view of the static random-access memory device of FIG. 1.

FIG. 3 shows a schematic cross-sectional view of the static random-access memory device illustrated along the line AA′ shown in FIG. 1.

FIG. 4 illustrates a schematic cross-sectional view of a static random-access memory device according to some embodiments of the present disclosure.

### DETAILED DESCRIPTION

Various embodiments will be described more fully hereinafter with reference to accompanying drawings. For clarity, the components may not be drawn to scale. The specification and the drawings are to be regarded as an illustrative sense rather than a restrictive sense. The illustration uses the same/similar reference numerals to indicate the same/similar elements. Moreover, use of ordinal terms such as “first”, “second”, “third”, etc., in the specification and claims to modify an element does not by itself imply any priority, precedence, or order of one claim element over another, but are used merely as labels to distinguish one claim element having a certain name from another element having the same name (but for use of the ordinal term) to distinguish the claim elements.

As used in the specification and the appended claims, spatial relation terms such as “on”, “above”, “over”, “upper,” “top”, “below”, “beneath”, “under”, “lower” and “bottom” be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Embodiments according to the present disclosure can be applied to many different types of fin field-effect transistor structures. For example, the embodiments can be applied to, but not limited to, static random-access memory devices including fin field-effect transistor structures. The following description uses a static random-access memory cell including eight transistors (8T) as an example to illustrate the concept of the present disclosure, but the present disclosure is not limited thereto. The present disclosure can also be applied to a static random-access memory cell including different numbers of transistors, such as a static random-access memory cell including six transistors (8T).

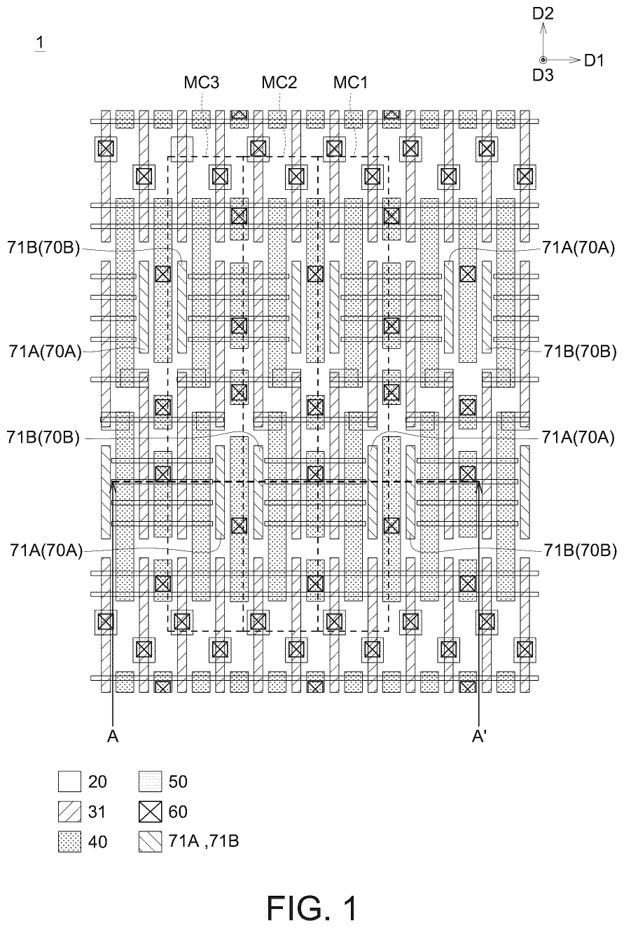

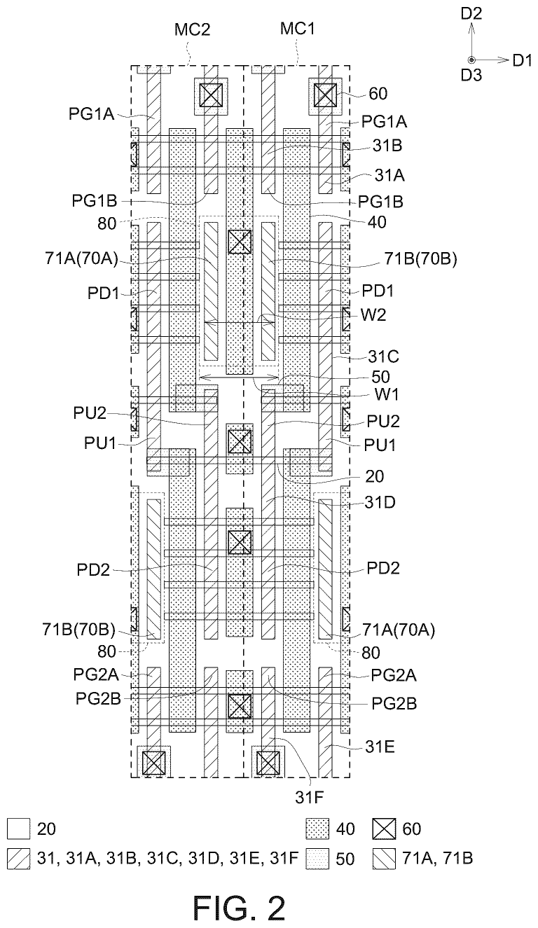

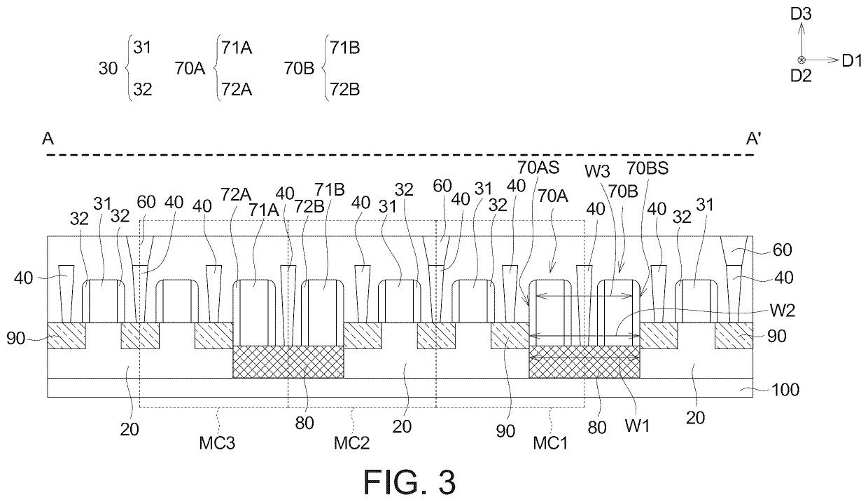

Referring to FIGS. 1 to 3, FIG. 1 illustrates a schematic top view or layout of a static random-access memory device 1 according to some embodiments of the present disclosure, FIG. 2 illustrates a schematic partial top view of the static random-access memory device 1 of FIG. 1, and FIG. 3 shows a schematic cross-sectional view of the static random-access memory device 1 illustrated along the line AA′ shown in FIG. 1.

The static random-access memory device 1 includes a plurality of static random-access memory cells MC1˜MC3. The static random-access memory cells MC1˜MC3 can be disposed along a first direction D1. The static random-access memory cell MC1 is adjacent to the static random-access memory cell MC2. The static random-access memory cell MC2 is between the static random-access memory cell MC1 and the static random-access memory cell MC3 and adjacent to the static random-access memory cell MC1 and the static random-access memory cell MC3. The static random-access memory cell MC3 is adjacent to the static random-access memory cell MC2. Each of the plurality of static random-access memory cells includes a pull-up transistor PU1, a pull-up transistor PU2, a pull-down transistor PD1, a pull-down transistor PD2, a pass-gate transistor PG1A, a pass-gate transistor PG1B, a pass-gate transistor PG2A, and a pass-gate transistor PG2B. The pull-up transistor PU1 and the pull-down transistor PD1 form a first inverter. The pull-up transistor PU2 and the pull-down transistor PD2 form a second inverter. Two inverters formed by the pull-up transistor PU1 and the pull-down transistor PD1, and the pull-up transistor PU2 and the pull-down transistor PD2 constitute a latch circuit for data storage. The first inverter can be cross-coupled with the second inverter, that is, the input terminal of the first inverter can be coupled to the output terminal of the second inverter, and the input terminal of the second inverter can be coupled to the output terminal of the first inverter. The output terminal of the first inverter can be called the first storage node, and the output terminal of the second inverter can be called the second storage node. In a general operating mode, the logical states of the first storage node and the second storage node are opposite. The source structure of the pull-up transistor PU1 and the source structure of the pull-up transistor PU2 are electrically connected to a voltage source Vcc. The source structure of the pull-down transistor PD1 and the source structure of the pull-down transistor PD2 are electrically connected to a voltage source Vss. The gate structures of the pass-gate transistor PG1A and the pass-gate transistor PG2A can be coupled to a word line, and the gate structures of the pass-gate transistor PG1B and the pass-gate transistor PG2B can be coupled to another word line. The source structures of the pass-gate transistor PG1A, the pass-gate transistor PG1B, the pass-gate transistor PG2A, and the pass-gate transistor PG2B can be coupled to different bit lines. The first storage node can be coupled to the gate structures of the pull-up transistor PU2 and the pull-down transistor PD2, and can be coupled to the drain structures of the pull-up transistor PU1, the pull-down transistor PD1, the pass-gate transistor PG1A and the pass-gate transistor PG1B. The second storage node can be coupled to the gate structures of the pull-up transistor PU1 and the pull-down transistor PD1, and can be coupled to the drain structures of the pull-up transistor PU2, the pull-down transistor PD2, the pass-gate transistor PG2A and the pass-gate transistor PG2B. The static random-access memory device 1 can be a dual-port static random-access memory device.

The pull-up transistor PU1 and the pull-up transistor PU2 can be P-type transistors, such as P-type metal-oxide-semiconductor field-effect transistor (PMOS). The pull-down transistor PD1, the pull-down transistor PD2, the pass-gate transistor PG1A, the pass-gate transistor PG1B, the pass-gate transistor PG2A, and the pass-gate transistor PG2B can be N-type transistors, such as N-type metal-oxide-semiconductor field-effect transistor (NMOS). In the present embodiment, the pull-up transistor PU1, the pull-up transistor PU2, the pull-down transistor PD1, the pull-down transistor PD2, the pass-gate transistor PG1A, the pass-gate transistor PG1B, the pass-gate transistor PG2A, and the pass-gate transistor PG2B have fin field-effect transistor structures.

The transistors included in the static random-access memory cell MC1 and the transistors included in the static random-access memory cell MC2 can be disposed symmetrically. The transistors included in the static random-access memory cell MC2 and the transistors included in the static random-access memory cell MC3 can be disposed symmetrically.

The static random-access memory device 1 includes a substrate 100, a plurality of fin structures 20 on the substrate 100, a plurality of gate elements 31 on the substrate 100, a plurality of contact structures 40 on the substrate 100, a plurality of contact layers 50 on the substrate 100, a plurality of via elements 60 on the substrate 100, a plurality of dummy gate elements 71A on the substrate 100, a plurality of dummy gate elements 71B on the substrate 100, a plurality of isolation structures 80 on the substrate 100, and a plurality of doping regions 90 on the substrate 100. The substrate 100 can be as semiconductor substrate, such as a silicon substrate or a silicon-on-insulator (SOI) substrate. The fin structures 20 may extend along a first direction D1. The fin structures 20 may be separated from each other. In the present embodiment, the fin structures 20 are disposed parallel to each other. The gate elements 31 may extend along a second direction D2. The first direction D1 is perpendicular to the second direction D2. The gate elements 31 may be separated from each other. In the present embodiment, the gate elements 31 are disposed parallel to each other. The gate element 31 extends across at least one fin structure 20. The static random-access memory device 1 can further includes gate spacers 32 on sidewalls of the gate elements 31, as shown in FIG. 3. The gate element 31 and the gate spacer 32 form a gate structure 30. The doping regions 90 are in the fin structures 20. The doping region 90 can be understood as a source/drain structure. The doping regions 90 are on opposite sides of the gate structure 30. In an embodiment, the doping region 90 can be formed by introducing P-type dopants or N-type dopants into the fin structure 20. A portion of the fin structure 20 below the gate structure 30 and between two doping regions 90 can be functioned as a channel.

The gate element 31, two doping regions 90 on opposite sides of this gate element 31, and the fin structure 20 across which this gate element 31 extends can form a transistor. For clarity, the gate elements 31 of the static random-access memory cell MC1 and the static random-access memory cell MC2 are indicated by gate elements 31A to 31F in FIG. 2, and the gate elements 31A to 31F all belong to gate elements 31. The gate element 31A, two doping regions 90 on opposite sides of the gate element 31A, and the fin structure 20 across which the gate element 31A extends form the pass-gate transistor PG1A. The gate element 31B, two doping regions 90 on opposite sides of the gate element 31B, and the fin structure 20 across which the gate element 31B extends form the pass-gate transistor PG1B. The gate element 31C, the doping regions 90 on opposite sides of the gate element 31C, and the fin structures 20 across which the gate element 31C extends form the pull-down transistor PD1 and the pull-up transistor PU1. The gate element 31D, the doping regions 90 on opposite sides of the gate element 31D, and the fin structures 20 across which the gate element 31D extends form the pull-down transistor PD2 and the pull-up transistor PU2. The gate element 31E, two doping regions 90 on opposite sides of the gate element 31E, and the fin structure 20 across which the gate element 31E extends form the pass-gate transistor PG2A. The gate element 31F, two doping regions 90 on opposite sides of the gate element 31F, and the fin structure 20 across which the gate element 31F extends form the pass-gate transistor PG2B. The pull-down transistor PD1 and the pull-up transistor PU1 share the same gate structure or gate element. The pull-down transistor PD2 and the pull-up transistor PU2 share the same gate structure or gate element.

The isolation structure 80 may be between the gate structures 30. The isolation structure 80 may be between the doping regions 90. The isolation structure 80 may be between adjacent two static random-access memory cells; for example, the isolation structure 80 can be between the static random-access memory cells MC1 and MC2, or can be between the static random-access memory cells MC2 and MC3. One of the isolation structures 80 can be between the pull-up transistor PU2 of the static random-access memory cell MC1, the pull-down transistor PD1 of the static random-access memory cell MC1, the pass-gate transistor PG1B of the static random-access memory cell MC1, the pull-up transistor PU2 of the static random-access memory cell MC2, the pull-down transistor PD1 of the static random-access memory cell MC2 and the pass-gate transistor PG1B of the static random-access memory cell MC2. Another one of the isolation structures 80 can be between the pull-up transistor PU1 of the static random-access memory cell MC2, the pull-down transistor PD2 of the static random-access memory cell MC2, the pass-gate transistor PG2A of the static random-access memory cell MC2, the pull-up transistor PU1 of the static random-access memory cell MC3, the pull-down transistor PD2 of the static random-access memory cell MC3 and the pass-gate transistor PG2A of the static random-access memory cell MC3. The relative positions of the other isolation structures 80 can be inferred in a similar manner. The dummy gate elements 71A may extend along the second direction D2. The dummy gate elements 71A may be separated from each other. The dummy gate elements 71B may extend along the second direction D2. The dummy gate elements 71B may be separated from each other. At least one dummy gate element 71A and at least one dummy gate element 71B (which can be referred to as corresponding dummy gate element 71B) are disposed on the same isolation structure 80. The dummy gate element 71A and the corresponding dummy gate element 71B are disposed along the first direction D1. The dummy gate element 71A and the corresponding dummy gate element 71B can be between adjacent two static random-access memory cells; for example, the dummy gate element 71A and the corresponding dummy gate element 71B can be between the static random-access memory cells MC1 and MC2, or between the static random-access memory cells MC2 and MC3. The dummy gate element 71A and the corresponding dummy gate element 71B may be separated from each other. The dummy gate element 71A and the corresponding dummy gate element 71B may be between the doping regions 90. In some embodiments, the dummy gate element 71A and the corresponding dummy gate element 71B are disposed parallel to each other. The static random-access memory device 1 can further includes dummy gate spacers 72A on sidewalls of the dummy gate elements 71A, as shown in FIG. 3. The dummy gate element 71A and the dummy gate spacer 72A form a dummy gate structure 70A. The static random-access memory device 1 can further includes dummy gate spacers 72B on sidewalls of the dummy gate elements 71B, as shown in FIG. 3. The dummy gate element 71B and the dummy gate spacer 72B form a dummy gate structure 70B. The dummy gate elements 71A and 71B are different from the gate element 31 in terms of electrical functions; the dummy gate elements 71A and 71B do not have electrical functions and are not used as transistors, while the gate element 31 has electrical functions and is used as a transistor. The transistor including the gate element 31 can be understood as an active transistor. The arrangement of dummy gate elements 71A and 71B can ensure the consistency of element density of the entire memory device.

In some embodiments, as shown in FIG. 3, the dummy gate structures 70A and 70B can be completely disposed on the isolation structure 80; that is, the dummy gate structures 70A and 70B can entirely overlap with the isolation structure 80 in a third direction D3; that is, the dummy gate element 71A and the dummy gate spacer 72A may not overlap with the fin structure 20 and the doping region 90 in the third direction D3, and the dummy gate element 71B and the dummy gate spacer 72B may not overlap with the fin structure 20 and the doping region 90 in the third direction D3. The first direction D1, the second direction D2 and the third direction D3 are perpendicular to each other. The third direction D3 can be perpendicular to an upper surface of the substrate 100. In the embodiment shown in FIG. 3, a lower surface of the dummy gate element 71A, a lower surface of the dummy gate spacer 72A, a lower surface of the dummy gate element 71B, and a lower surface of the dummy gate spacer 72B directly contact an upper surface of the isolation structure 80, and are entirely covered by the isolation structure 80. An area of the upper surface of the isolation structure 80 (e.g. the isolation structure 80 indicated by dotted lines in FIG. 2) can be greater than the sum of an area of the lower surface of the dummy gate structure 70A and an area of the lower surface of the dummy gate structure 70B. The area of the lower surface of the dummy gate structure 70A can be defined as the sum of an area of a lower surface of the dummy gate element 71A and an area of the lower surface of the dummy gate spacer 72A. The area of the lower surface of the dummy gate structure 70B can be defined as the sum of an area of a lower surface of the dummy gate element 71B and an area of the lower surface of the dummy gate spacer 72B. In other embodiments, the dummy gate structures 70A and 70B can be disposed partially on the isolation structure 80; that is, the dummy gate element 71A and the dummy gate element 71B can entirely overlap with the isolation structure 80 in the third direction D3, and the dummy gate spacers 72A and 72B can partially overlap with the fin structure 20 and/or the doping region 90 and partially overlap with the isolation structure 80 in the third direction D3. In the present embodiment, the lower surface of the dummy gate element 71A and the lower surface of the dummy gate element 71B can directly contact the upper surface of the isolation structure 80 and be entirely covered by the isolation structure 80.

The isolation structure 80 has a width W1 in the first direction D1. The dummy gate structure 70A and the corresponding dummy gate structure 70B have a width W2 in the first direction D1. The dummy gate element 71A and the corresponding dummy gate element 71B have a width W3 in the first direction D1. The width W2 can be defined as a distance between a sidewall 70AS of the dummy gate structure 70A and a sidewall 70BS of the corresponding dummy gate structure 70B along the first direction D1. The sidewall 70BS faces away from the dummy gate structure 70A. The sidewall faces 70AS away from the corresponding dummy gate structure 70B. The dummy gate spacer 72A of the dummy gate structure 70A has the sidewall 70AS. The dummy gate spacer 72B of the dummy gate structure 70B has the sidewall 70BS. The width W2 can be defined as a maximum width of the dummy gate structure 70A and the corresponding dummy gate structure 70B in the first direction D1. The width W3 can be defined as a maximum width of the dummy gate element 71A and the corresponding dummy gate element 71B in the first direction D1. In some embodiments, the width W1 is equal to the width W2, as shown in FIG. 3. The width W1 is greater than the width W3. The width W2 is greater than the width W3. The isolation structure 80 can be used as a diffusion break structure. A length of the isolation structure 80 in the second direction D2 can be greater than or equal to a length of the dummy gate element 71A in the second direction D2. The isolation structure 80 has two side surface opposite to each other, wherein one side surface can be aligned with the sidewall 70AS of the dummy gate structure 70A in the third direction D3, and the other side surface can be aligned with the sidewall 70BS of the dummy gate structure 70B in the third direction D3. An upper surface of the isolation structure 80 can be lower than an upper surface of the fin structure 20 and an upper surface of the doping region 90 in the third direction D3.

As shown in FIG. 3, the sidewall 70AS of the dummy gate structure 70A can contact the doping region 90 (or the source structure or drain structure of the pull-down transistor PD1/PD2 of the static random-access memory cell). As shown in FIG. 3, the sidewall 70BS of the dummy gate structure 70B can contact the doping region 90 (or the source structure or drain structure of the pull-down transistor PD1/PD2 of the static random-access memory cell).

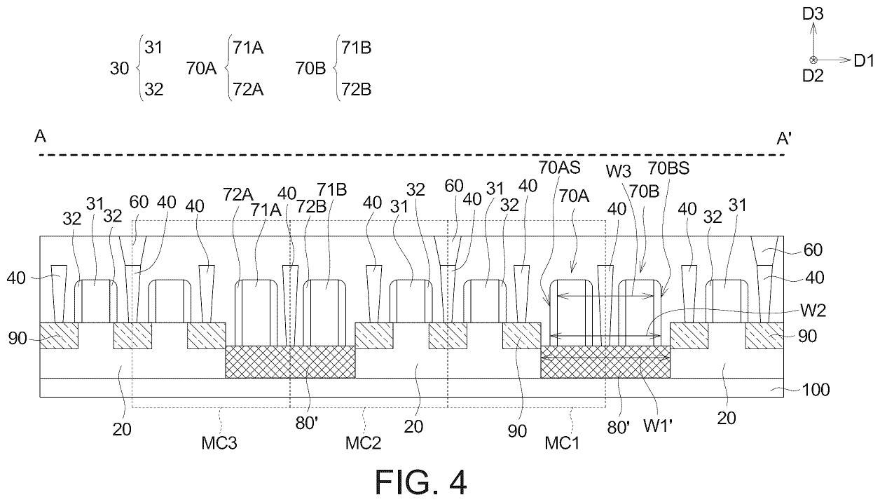

In other embodiments, at least one of the sidewall 70AS of the dummy gate structure 70A and the sidewall 70BS of the dummy gate structure 70B may not contact the doping regions 90, as shown in FIG. 4. In FIG. 4, the isolation structure 80′ extend beyond the dummy gate structure 70A and the corresponding dummy gate structure 70B in the first direction D1, the isolation structure 80′ extend beyond the dummy gate element 71A and the corresponding dummy gate element 71B in the first direction D1, and the sidewall 70AS of the dummy gate structure 70A and the sidewall 70BS of the dummy gate structure 70B do not contact the doping region 90. The isolation structure 80′ has a width W1′ in the first direction D1. The dummy gate structure 70A and the corresponding dummy gate structure 70B have the width W2 in the first direction D1. The dummy gate element 71A and the corresponding dummy gate element 71B have the width W3 in the first direction D1. The width W1′ can be greater than the width W2 and greater than the width W3.

The static random-access memory device 1 includes an active region and a passive region. The static random-access memory cells are in the active region. The isolation structure 80, the dummy gate structure 70A and the dummy gate structure 70B are in the active region. In some embodiments, the static random-access memory device 1 includes passive elements such as capacitor, resistor, and inductor in the passive region.

The contact structures 40 may extend along the second direction D2. The contact structures 40 may be separated from each other. In the present embodiment, the contact structure 40 are disposed parallel to each other. Some of the contact structures 40 are disposed on the doping regions 90 and electrically connected to the doping regions 90. Some of the contact structures 40 are disposed on the isolation structures 80 and between the dummy gate structures 70A and the corresponding dummy gate structures 70B. The contact layers 50 may be separated from each other. Some of the contact layers 50 may extend along the first direction D1 and extend across the contact structures 40 and the gate structures 30 to provide electrical connections between the contact structures 40 and the gate structures 30. Some of the contact layers 50 may be on the gate structures 30 and electrically connected to the gate structures. Some of the via elements 60 may be on the contact structures 40 and electrically connected to the contact structures 40. Some of the via elements 60 may be on the contact layers 50 and electrically connected to the contact layers 50.

The present disclosure provides a static random-access memory device including an isolation structure 80/80′ and a dummy gate structure 70A/70B on the isolation structure 80/80′. The width of the isolation structure 80/80′ along the first direction D1 is greater than or equal to the distance between the sidewall 70AS of the dummy gate structure 70A and the sidewall 70BS of the dummy gate structure 70B along the first direction D1, and/or the lower surface of the dummy gate structure 70A/70B is entirely covered by the isolation structure 80/80′ (i.e. the dummy gate structure 70A/70B does not overlap with the fin structure 20 in the third direction D3). Therefore, the leakage current can be reduced or avoided, and the electrical performance of the memory device can be improved.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A static random-access memory device, comprising:
a first static random-access memory cell;
a second static random-access memory cell adjacent to the first static random-access memory cell;
an isolation structure between the first static random-access memory cell and the second static random-access memory cell;
a first dummy gate structure on the isolation structure and between the first static random-access memory cell and the second static random-access memory cell; and
a second dummy gate structure on the isolation structure and between the first static random-access memory cell and the second static random-access memory cell, wherein the first dummy gate structure and the second dummy gate structure are disposed along a first direction,
wherein a width of the isolation structure along the first direction is greater than or equal to a distance between a first sidewall of the first dummy gate structure and a second sidewall of the second dummy gate structure along the first direction, the first sidewall faces away from the second dummy gate structure, and the second sidewall faces away from the first dummy gate structure.

2. The static random-access memory device according to claim 1, wherein the first dummy gate structure includes a first dummy gate element and a first dummy gate spacer on a sidewall of the first dummy gate element, the second dummy gate structure includes a second dummy gate element and a second dummy gate spacer on a sidewall of the second dummy gate element, the first dummy gate spacer has the first sidewall, and the second dummy gate spacer has the second sidewall.

3. The static random-access memory device according to claim 1, wherein the first sidewall is aligned with a side surface of the isolation structure, and the second sidewall is aligned with another side surface of the isolation structure.

4. The static random-access memory device according to claim 1, further comprising a contact structure extending along a second direction and disposed on the isolation structure, the second direction is perpendicular to the first direction.

5. The static random-access memory device according to claim 1, wherein the isolation structure, the first dummy gate structure and the second dummy gate structure are in an active region of the static random-access memory device.

6. The static random-access memory device according to claim 1, wherein the isolation structure is between a pull-up transistor of the first static random-access memory cell, a pull-down transistor of the first static random-access memory cell, a pass-gate transistor of the first static random-access memory cell, a pull-up transistor of the second static random-access memory cell, a pull-down transistor of the second static random-access memory cell and a pass-gate transistor of the second static random-access memory cell.

7. A static random-access memory device, comprising:
a plurality of static random-access memory cells, wherein each of the plurality of static random-access memory cells comprises two pull-up transistors, two pull-down transistors and two pass-gate transistors;
an isolation structure between adjacent two static random-access memory cells of the plurality of static random-access memory cells; and
a first dummy gate element on the isolation structure,
wherein a lower surface of the first dummy gate element is entirely covered by the isolation structure.

8. The static random-access memory device according to claim 7, wherein the first dummy gate element entirely overlaps with the isolation structure in a first direction.

9. The static random-access memory device according to claim 7, further comprising a first dummy gate spacer on a sidewall of the first dummy gate element, the first dummy gate spacer contacts a source structure or a drain structure of the pull-down transistors.

10. The static random-access memory device according to claim 7, further comprising a second dummy gate element on the isolation structure and separated from the first dummy gate element, a lower surface of the second dummy gate element is entirely covered by the isolation structure.

11. The static random-access memory device according to claim 10, wherein the second dummy gate element entirely overlaps with the isolation structure in a first direction.

12. The static random-access memory device according to claim 10, wherein the first dummy gate element and the second dummy gate element are disposed along a first direction, the isolation structure extends beyond the first dummy gate element and the second dummy gate element in the first direction.

13. The static random-access memory device according to claim 7, wherein the isolation structure and the first dummy gate element are in an active region of the static random-access memory device.

14. The static random-access memory device according to claim 7, further comprising a contact structure on the isolation structure.
